(19) United States
(12) Patent Application Publication
(10) Pub. No.: US 2026/0012139 A1
(43) Pub. Date: Jan. 8, 2026

(54) POWER AMPLIFIER CIRCUIT

(71) Applicant: Murata Manufacturing Co., Ltd., Nagaokakyo-shi (JP)

(72) Inventor: Masatoshi HASE, Nagaokakyo-shi (JP)

(21) Appl. No.: 19/244,527

(22) Filed: Jun. 20, 2025

(30) Foreign Application Priority Data
Jul. 5, 2024 (JP) 2024-108974

(51) Int. Cl. H03F 1/32; H03F 1/56; H03F 3/45

(52) U.S. Cl. CPC H03F 1/3211; H03F 1/56; H03F 3/45475; H03F 2200/165; H03F 2200/168; H03F 2200/451

(57) ABSTRACT

A power amplifier circuit includes an isolation circuit, an impedance conversion circuit, and an amplifier circuit. The isolation circuit includes a second-harmonic attenuation unit and a fundamental attenuation unit. The second-harmonic attenuation unit, which receives a first signal obtained through division of an input signal, passes fundamental waves of the first signal, and attenuates second harmonic waves of the first signal. The fundamental attenuation unit, which receives a second signal obtained through division of the input signal, passes second harmonic waves of the second signal, and attenuates fundamental waves of the second signal. The isolation circuit outputs, from a combination point, a combined signal obtained by combining the first signal, which has passed through the second-harmonic attenuation unit, with the second signal, which has passed through the fundamental attenuation unit.

### CROSS REFERENCE TO RELATED APPLICATION

This application claims priority from Japanese Patent Application No. 2024-108974, filed on Jul. 5, 2024. The content of these applications are incorporated herein by reference in its entirety.

### BACKGROUND OF THE DISCLOSURE

### 1. Field of the Disclosure

The present disclosure relates to a power amplifier circuit.

### 2. Description of the Related Art

Mobile communication devices such as cellular phones include a power amplifier circuit for amplifying power of a transmit signal. When such a power amplifier circuit is supplied, for example, with multiple signals having close frequencies, these signals may cause inter-modulation distortion (IMD) to occur, resulting in degradation of linearity of gain. A technique has been proposed which cancels inter-modulation distortion components through deliberate injection of harmonics to a signal path to suppress influence of inter-modulation distortion.

For example, U.S. Pat. No. 11,309,849 discloses a distortion compensation circuit which compensates inter-modulation distortion by providing a filter circuit which attenuates fundamental waves in an output from an initial-stage amplifier and which passes second harmonic waves.

### BRIEF SUMMARY OF THE DISCLOSURE

Recently, due to introduction of a new communication standard, such as the fifth-generation mobile communication system (5G) or the sixth-generation mobile communication system (6G), output power of a transmit signal transmitted by a cellular phone tends to increase. If, to increase output power, a power-stage amplifier circuit is formed of many transistors connected in parallel to each other, the input impedance of the amplifier circuit decreases. In the device disclosed in U.S. Pat. No. 11,309,849, isolation between the main path, through which fundamental waves pass, and the secondary path, through which second harmonic waves pass, is ensured by using a low-pass filter disposed on the main path.

However, the device disclosed in U.S. Pat. No. 11,309,849 has an issue in that, when the input impedance of the power-stage amplifier circuit is small, the low-pass filter fails to attenuate harmonics, resulting in failure to ensure isolation between the main path and the secondary path. Thus, influence of inter-modulation distortion fails to be suppressed.

The present disclosure is made in view of the situation, and a possible benefit thereof is to provide a power amplifier circuit which is capable of suppressing influence of inter-modulation distortion.

To attain the possible benefit, a power amplifier circuit according to an aspect of the present disclosure includes an isolation circuit, an impedance conversion circuit, and an amplifier circuit. The isolation circuit includes a second-harmonic attenuation unit which receives a first signal obtained through division of an input signal and which passes a fundamental wave of the first signal and attenuates a second harmonic wave of the first signal, and a fundamental attenuation unit which receives a second signal obtained through division of the input signal and which passes a second harmonic wave of the second signal and attenuates a fundamental wave of the second signal. The isolation circuit outputs, from a combination point thereof, a combined signal obtained by combining the first signal having passed through the second-harmonic attenuation unit, with the second signal having passed through the fundamental attenuation unit. The impedance conversion circuit receives, at an input point thereof, the combined signal, and outputs, from an output point thereof, an output combined signal obtained through impedance conversion of the combined signal. The impedance conversion circuit includes a transmission line transformer. The impedance conversion circuit performs the impedance conversion to make impedance at the input point larger than impedance at the output point. The amplifier circuit amplifies the combined signal to output an amplified signal.

The present disclosure may provide a power amplifier circuit which is capable of suppressing influence of inter-modulation distortion.

### BRIEF DESCRIPTION OF THE SEVERAL VIEWS OF THE DRAWINGS

FIG. 1 is a diagram illustrating a configuration example of a power amplifier circuit according to the present embodiment;

FIG. 2 is a diagram illustrating the spectrum of a signal supplied to a power-stage amplifier circuit;

FIG. 3 is a diagram illustrating cancellation of third-order inter-modulation distortion of a signal outputted from a power-stage amplifier circuit;

FIG. 4 is a diagram illustrating a configuration example of a combining circuit;

FIG. 5 is a diagram illustrating a configuration example of a combining circuit of a power amplifier circuit according to a first modified example;

FIG. 6 is a diagram illustrating a configuration example of a combining circuit of a power amplifier circuit according to a second modified example;

FIG. 7 is a diagram illustrating a configuration example of a combining circuit of a power amplifier circuit according to a third modified example;

FIG. 8 is a diagram illustrating a configuration example of a combining circuit of a power amplifier circuit according to a fourth modified example;

FIG. 9 is a diagram illustrating a configuration example of a combining circuit of a power amplifier circuit according to a fifth modified example;

FIG. 10 is a diagram illustrating a configuration example of a combining circuit of a power amplifier circuit according to a sixth modified example; and

FIG. 11 is a diagram illustrating a configuration example of a combining circuit of a power amplifier circuit according to a seventh modified example.

### DETAILED DESCRIPTION OF THE DISCLOSURE

Embodiment of the present disclosure will be described below in detail by referring to the drawings. The same components are designated with the same reference numerals, and repeated description will be avoided.

### Power Amplifier Circuit 100

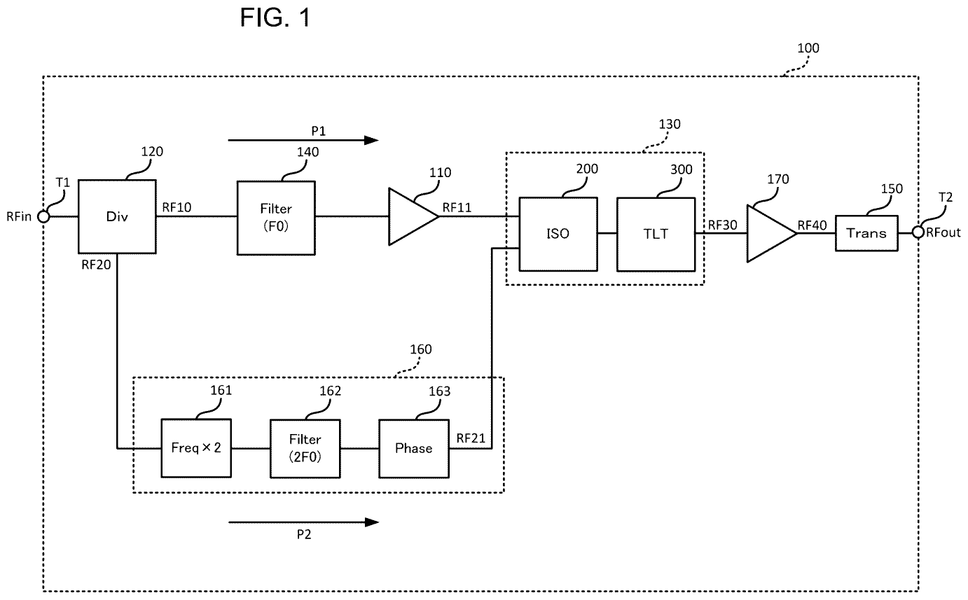

FIG. 1 is a diagram illustrating a configuration example of a power amplifier circuit 100 according to the present embodiment. The power amplifier circuit 100 illustrated in FIG. 1 is included, for example, in a mobile communication device such as a cellular phone, and is used to amplify power of a radio-frequency (RF) signal that is to be transmitted to a base station. For example, the power amplifier circuit 100 amplifies power of a signal of a communication standard, such as the second-generation mobile communication system (2G), the third-generation mobile communication system (3G), the fourth-generation mobile communication system (4G), the fifth-generation mobile communication system (5G), long term evolution (LTE)-frequency division duplex (FDD), LTE-time division duplex (TDD), LTE-Advanced, LTE-Advanced Pro, or the sixth-generation mobile communication system (6G). The frequency of an RF signal is, for example, on the order of several hundreds of MHz to several tens of GHz. The communication standard and the frequency of a signal that is amplified by the power amplifier circuit 100 are not limited to these.

The power amplifier circuit 100 is an amplifier circuit which is capable of suppressing third-order inter-modulation distortion. The power amplifier circuit 100 has a path (hereinafter referred to as a “main path P1”) for passing fundamental waves in the frequency band of an input signal RFin, and a path (hereinafter referred to as a “secondary path P2”) for generating, from the input signal RFin, second harmonic waves in the frequency band which is double the frequency band of the fundamental waves. The power amplifier circuit 100 inputs, to a power-stage amplifier circuit 170, a signal RF30 obtained by a combining circuit 130 combining a fundamental F₀, which has passed through the main path P1, with a second harmonic 2F₀, which has been generated along the secondary path P2.

The power amplifier circuit 100 needs to ensure isolation, in the combining circuit 130, between the main path P1, through which the fundamental F₀ passes, and the secondary path P2, through which the second harmonic 2F₀ passes. This enables the power amplifier circuit 100 to appropriately suppress third-order inter-modulation distortion.

As illustrated in FIG. 1, the power amplifier circuit 100 includes, for example, an amplifier circuit 110, a divider 120, the combining circuit 130, a filter circuit 140, a harmonic termination circuit 150, a distortion compensation circuit 160, the amplifier circuit 170, an input terminal T1, and an output terminal T2. The power amplifier circuit 100 includes the main path P1 and the secondary path P2.

Each of the amplifier circuits 110 and 170 amplifies a received RF signal for output. That is, the power amplifier circuit 100 amplifies power, for example, in two stages. Specifically, the initial-stage (driving-stage) amplifier circuit 110 amplifies a signal RF10, which is received from the input terminal T1 through the filter circuit 140, to output a signal RF11 (first signal). The subsequent-stage (power-stage) amplifier circuit 170 amplifies the signal RF30, which is obtained through combination performed by the combining circuit 130 described below, to output a signal RF40. The signal RF40 contains second harmonic waves which occur due to amplification operation of the amplifier circuit 170.

Each of the amplifier circuits 110 and 170 is formed, for example, of a bipolar transistor such as a heterojunction bipolar transistor (HBT). Each of the amplifier circuits 110 and 170 may be formed of a metal-oxide-semiconductor field-effect transistor (MOSFET) instead of an HBT.

The divider 120 divides the signal RFin, which is received from the input terminal T1, to output the signal RF10 to the main path P1 and output a signal RF20 to the secondary path P2. The main path P1 is a path from the input terminal T1 through the driving-stage amplifier circuit 110 to the combining circuit 130. The main path P1 is a path for passing the fundamental F₀ of the signal RFin. The secondary path P2 is a path from the divider 120 through the distortion compensation circuit 160 to the combining circuit 130. The secondary path P2 is a path for generating the second harmonic 2F₀ for compensating third-order inter-modulation distortion occurring in the subsequent-stage amplifier circuit 170.

The combining circuit 130 combines the fundamental F₀ (signal RF11), which is received through the main path P1, with the second harmonic 2F₀ (signal RF21), which is received through the secondary path P2, to generate the signal RF30. The generated signal RF30 is supplied to the subsequent-stage amplifier circuit 170. The combining circuit 130 has a circuit which is capable of ensuring isolation between the main path P1 and the secondary path P2. The configuration of the combining circuit 130 will be described in detail below.

The filter circuit 140 is a circuit for passing the fundamental F₀ of the input signal RFin.

The harmonic termination circuit 150 is disposed downstream of the amplifier circuit 170. The harmonic termination circuit 150 short-circuits, for example, second harmonic waves, which are contained in the signal RF40, to the ground. Thus, an output signal RFout, from which second harmonic waves have been attenuated, is outputted from the output terminal T2. The harmonic termination circuit 150 may have a function of matching the impedance between the amplifier circuit 170 and a circuit downstream of the output terminal T2.

The distortion compensation circuit 160 is disposed between the divider 120 and the combining circuit 130 on the secondary path P2. The distortion compensation circuit 160 generates, for amplification and output, the second harmonic 2F₀ which is to be injected deliberately to compensate the third-order inter-modulation distortion. Specifically, the distortion compensation circuit 160 may include, for example, a harmonic generating circuit 161, a filter circuit 162, and a phase adjustment circuit 163.

The harmonic generating circuit 161 generates the second harmonic 2F₀ on the basis of the signal RF20 supplied from the divider 120 to the secondary path P2. For example, the harmonic generating circuit 161 may be formed of an amplifier circuit which amplifies the signal RF20, or may be formed of a multiplier circuit which doubles the frequency of the fundamental F₀ supplied from the divider 120 to the secondary path P2.

The filter circuit 162 is disposed, for example, downstream of the harmonic generating circuit 161. The filter circuit 162 has frequency characteristics of attenuating the fundamental F₀ and passing the second harmonic 2F₀. Thus, for example, when the previous-stage harmonic generating circuit 161 is formed of an amplifier circuit, only the second harmonic 2F₀, which is needed for distortion compensation, in a signal outputted from the amplifier circuit is extracted. The filter circuit 162 may be formed, for example, of a high pass filter (HPF) circuit or a band pass filter (BPF) circuit which attenuates the fundamental F₀ and passes the second harmonic 2F₀.

The phase adjustment circuit 163 is disposed, for example, downstream of the filter circuit 162. The phase adjustment circuit 163 makes adjustment so that the phase of the generated second harmonic 2F₀ is set to the phase suitable for distortion compensation, and outputs the signal RF21.

The configuration described above enables the distortion compensation circuit 160 to generate the second harmonic 2F₀ which is to be deliberately injected to an input of the amplifier circuit 170. The order of the components included in the distortion compensation circuit 160 is not limited to this, and may be changed appropriately. The distortion compensation circuit 160 may include a matching circuit which matches the impedance between the phase adjustment circuit 164 and the amplifier circuit 170. Hereinafter, the signal RF11 may be referred to as the “fundamental F₀”, and the signal RF21 may be referred to as the “second harmonic 2F₀”.

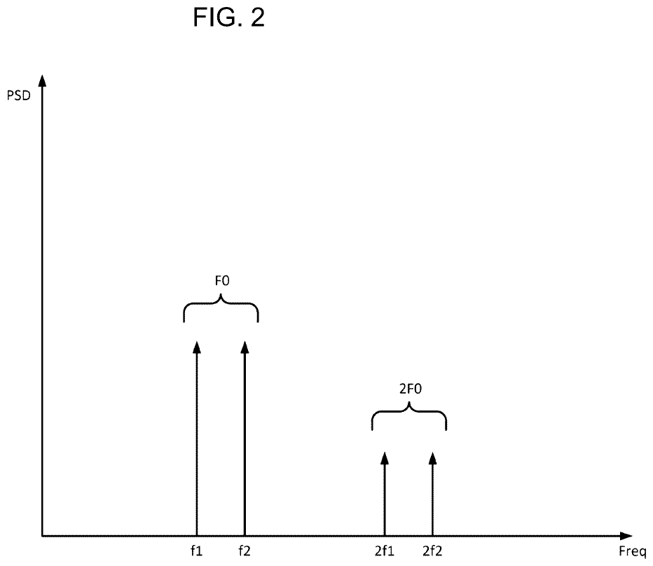

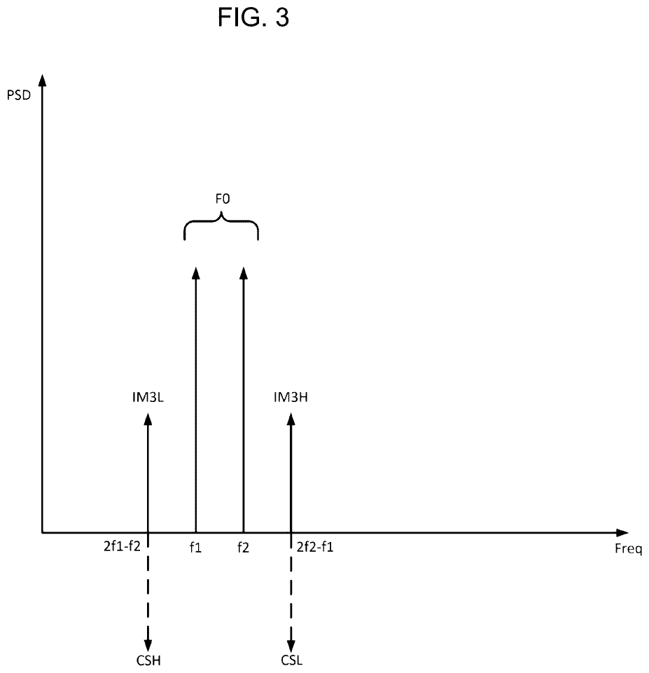

Referring to FIGS. 2 and 3, an operation of compensating third-order inter-modulation distortion will be described. FIG. 2 is a diagram illustrating the spectrum of a signal (in this example, the signal RF30 in FIG. 1) supplied to the power-stage amplifier circuit 170. Although the signal RF30 contains signal components of higher harmonic equal to or higher than the third harmonic, FIG. 2 does not illustrate such components. The second-harmonic signal components cause third-order inter-modulation distortion to occur. FIG. 3 is a diagram illustrating cancellation of the third-order inter-modulation distortion of a signal (in this example, the signal RF40 in FIG. 1) outputted from the power-stage amplifier circuit 170.

FIGS. 2 and 3 illustrate, for example, the fundamental F₀ and the second harmonic 2F₀ which are contained in a signal supplied to the amplifier circuit 170. In FIGS. 2 and 3, the horizontal axis indicates signal frequency; the vertical axis indicates power spectral density (PSD).

As illustrated in FIG. 2, the amplifier circuit 170 is supplied with the fundamental F₀, which is received through the main path P1, and the second harmonic 2F₀, which is received through the secondary path P2. Assume that the fundamental F₀ contains components of two frequencies f₁ and f₂ (f₁<f₂) which are close to each other. In this case, along the secondary path P2, the second harmonic 2F₀ of frequencies corresponding to the respective frequencies f₁ and f₂ is generated. That is, the second harmonic 2F₀ contains components of two frequencies 2f₁ and 2f₂. Therefore, the amplifier circuit 170 is supplied with a signal obtained by combining the fundamental F₀ of the frequencies f₁ and f₂ with the second harmonic 2F₀₁ of the frequencies 2f₁ and 2f₂.

The amplifier circuit 170 having non-linearity amplifies fundamental waves, so that a third-order inter-modulation distortion IM3_{L} having a frequency of 2f₁−f₂ occurs on the lower side of the signal F₀₁ of the fundamental (frequency f₁), and a third-order inter-modulation distortion IM3_{H} having a frequency of 2f₂−f₁ occurs on the higher side of the signal F₀₁ of the fundamental (frequency f₂).

The third-order inter-modulation distortions IM3_{L} and IM3_{H}, which occur at that time, are relatively close to the frequencies f₁ and f₂ of the fundamental F₀. Therefore, it is difficult to remove the third-order inter-modulation distortions IM3_{L} and IM3_{H}, for example, by using a filter circuit. The third-order inter-modulation distortions IM3_{L} and IM3_{H} may cause degradation of the linearity of the power amplifier circuit 100. The amplifier circuit 170's amplification operation of fundamental waves may cause occurrence of third-order inter-modulation distortions, for example, of frequencies of 2f₁+f₂ and 2f₂+f₁. However, since the frequencies of such distortions are relatively far from the frequencies f₁ and f₂ of the fundamental F₀, the influence on degradation of the linearity is small. Accordingly, such third-order inter-modulation distortions will not be described.

The power amplifier circuit 100 compensates the third-order inter-modulation distortions IM3_{L} and IM3_{H} which are relatively close to the fundamental waves. As described above, in the power amplifier circuit 100, the second harmonic 2F₀ is deliberately combined with the fundamental F₀ to generate compensation signals CS_{L} and CS_{H} for canceling the third-order inter-modulation distortions IM3_{L} and IM3_{H}.

Specifically, in the power amplifier circuit 100, the amplifier circuit 170 amplifies the fundamental F₀ and the second harmonic 2F₀, which have been added to each other. At that time, the compensation signal CS_{L} having the frequency (2f₁−f₂) which is the difference between a first one of the frequencies of the second harmonic 2F₀, that is, the frequency 2f₁, and a second one of the frequencies of the fundamental F₀, that is, the frequency f₂, is generated.

In the power amplifier circuit 100, the compensation signal CS_{H} having the frequency (2f₂−f₁) which is the difference between a second one of the frequencies of the second harmonic 2F₀, that is, the frequency 2f₂, and a first one of the frequencies of the fundamental F₀, that is, the frequency f₁, is generated.

Thus, in the power amplifier circuit 100, the distortion compensation circuit 160 adjusts the phase of the second harmonic 2F₀ so that, in an output of the amplifier circuit 170, the phases of the third-order inter-modulation distortions IM3_{L} and IM3_{H}, which occur in the amplifier circuit 170, are different by about 180° from the phases of the compensation signals CS_{L} and CS_{H}.

In the power amplifier circuit 100, the distortion compensation circuit 160 may adjust the amplitude of the second harmonic 2F₀₁ through gain adjustment performed by the harmonic generating circuit 161 so that the amplitudes of the third-order inter-modulation distortions IM3_{L} and IM3_{H}, which occur in the amplifier circuit 170, and those of the compensation signals CS_{L} and CS_{H} cancel each other out in an output of the amplifier circuit 170.

For a fundamental F₀₂, like the fundamental F₀₁, a second harmonic 2F₀₂ is adjusted to cancel third-order inter-modulation distortion, which is not described.

Thus, as illustrated in FIG. 3, the power amplifier circuit 100 cancels the third-order inter-modulation distortions IM3_{L} and IM3_{H} by using the compensation signals CS_{L} and CS_{H}. In FIG. 3, the compensation signals CS_{L} and CS_{H} are illustrated pointing downward to indicate that the compensation signals CS_{L} and CS_{H} are different in phase by about 180° from the third-order inter-modulation distortions IM3_{L} and IM3_{H}.

The operation described above causes the power amplifier circuit 100 to achieve suppression of influence of the third-order inter-modulation distortions IM3_{L} and IM3_{H} which occur in the amplifier circuit 170. Thus, the power amplifier circuit 100 achieves suppression of degradation of linearity of gain.

That is, failure to ensure isolation between the main path P1 and the secondary path P2 causes the following problem to arise in the power amplifier circuit 100. Among components of the second harmonic 2F₀ deliberately combined with the fundamental F₀, components flowing to the output terminal of the amplifier circuit 110 on the main path P1 occur other than components flowing to the input terminal of the amplifier circuit 170. The components flowing to the output terminal of the amplifier circuit 110 cause the amplifier circuit 110 to generate new inter-modulation distortion components. The new generated inter-modulation distortion components are amplified by the amplifier circuit 170 for output from the output terminal T2 of the power amplifier circuit 100. Therefore, even when the inter-modulation distortion components in the amplifier circuit 170 are canceled appropriately through deliberate combination of the second harmonic 2F₀ with the fundamental F₀, the inter-modulation distortion, which newly occurs in the amplifier circuit 110, is outputted from the output terminal T2 of the power amplifier circuit 100. Therefore, the power amplifier circuit 100 includes the combining circuit 130 which is capable of ensuring isolation between the main path P1 and the secondary path P2.

### Combining Circuit 130

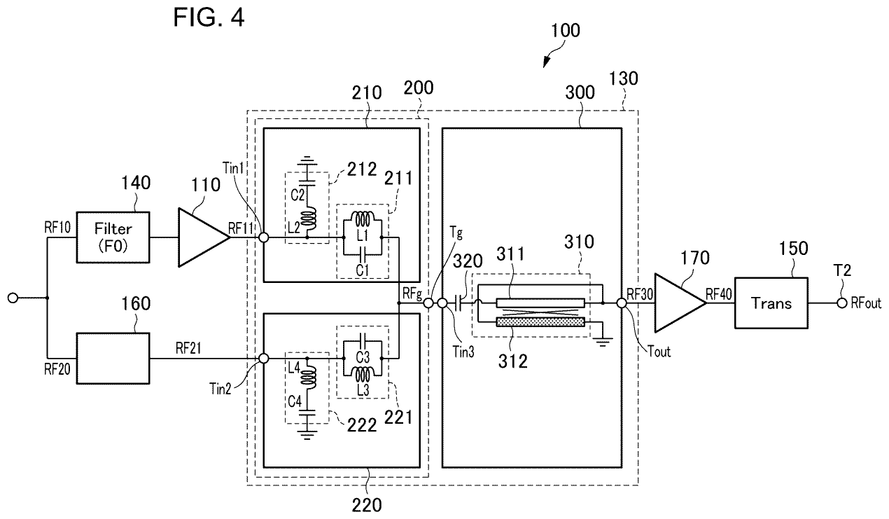

Referring to FIG. 4, the configuration of the combining circuit 130 will be described. FIG. 4 is a diagram illustrating a configuration example of the combining circuit 130.

The combining circuit 130 is a circuit which combines the fundamental F₀, which is received through the main path P1, with the second harmonic 2F₀, which is received through the secondary path P2, while isolation between the main path P1 and the secondary path P2 is ensured. As illustrated in FIG. 4, the combining circuit 130 includes, for example, an isolation circuit 200 and an impedance conversion circuit 300.

The isolation circuit 200 is a circuit which ensures isolation between the main path P1 and the secondary path P2. The isolation circuit 200 outputs, from a combination point Tg to the impedance conversion circuit 300, a signal RFg obtained by combining the signal RF11, which is fundamental waves, with the signal RF21, which is second harmonic waves.

As illustrated in FIG. 4, the isolation circuit 200 includes, for example, a second-harmonic attenuation unit 210 and a fundamental attenuation unit 220.

The second-harmonic attenuation unit 210 is a circuit which receives the signal RF11 (fundamental F₀) through the main path P1, and which passes fundamental waves and attenuates second harmonic waves. Thus, the second-harmonic attenuation unit 210 attenuates second harmonic waves, which flow from the secondary path P2 to the main path P1, to ensure isolation of the main path P1 with respect to the secondary path P2. The second-harmonic attenuation unit 210 may be a circuit which attenuates only the second harmonic, or may be a circuit which attenuates higher harmonics equal to or higher than the second harmonic.

The second-harmonic attenuation unit 210 includes, for example, a first filter circuit 211, a second filter circuit 212, and an input point Tin1.

The first filter circuit 211 is connected in series between the input point Tin1, at which the signal RF11 is received, and the combination point Tg. The first filter circuit 211 is a circuit which includes at least one parallel resonant circuit. Specifically, the first filter circuit 211 is a circuit including, for example, a capacitor C1 and an inductor L1 connected in parallel to each other.

The second filter circuit 212 is connected in series between a reference potential (for example, the ground) and a node N1 between the input point Tin1 and the combination point Tg. The second filter circuit 212 is a circuit which includes at least one series resonant circuit. Specifically, the second filter circuit 212 is a circuit including, for example, a capacitor C2 and an inductor L2 connected in series to each other.

The fundamental attenuation unit 220 is a circuit which receives the signal RF21 (second harmonic 2F₀) through the secondary path P2 and which passes second harmonic waves and attenuates fundamental waves. Thus, the fundamental attenuation unit 220 attenuates fundamental waves, which flow from the main path P1 to the secondary path P2, to ensure isolation of the secondary path P2 with respect to the main path P1. The fundamental attenuation unit 220 may be a circuit which attenuates only fundamental waves, or may be a circuit which attenuates, in addition to fundamental waves, higher harmonic waves other than the second harmonic.

The fundamental attenuation unit 220 includes, for example, a third filter circuit 221, a fourth filter circuit 222, and an input point Tin2.

The third filter circuit 221 is connected in series between the input point Tin2, at which the signal RF21 is received, and the combination point Tg. The third filter circuit 221 is a circuit which includes at least one parallel resonant circuit. Specifically, the third filter circuit 221 is a circuit including, for example, a capacitor C3 and an inductor L3 connected in parallel to each other.

The fourth filter circuit 222 is connected in series between a reference potential (for example, the ground) and a node N2 between the input point Tin2 and the combination point Tg. The fourth filter circuit 242 is a circuit which includes at least one series resonant circuit. Specifically, the fourth filter circuit 222 is a circuit including, for example, a capacitor C4 and an inductor L4 connected in series to each other.

The impedance conversion circuit 300 is a circuit which converts the impedance. The impedance conversion circuit 300 receives the signal RFg at an input point Tin3, and outputs, from an output point Tout to the amplifier circuit 170, the signal RF30 obtained through impedance conversion of the signal RFg. Specifically, the impedance conversion circuit 300 converts the impedance so that the impedance at the input point Tin3 on the isolation circuit 200 side is higher than the impedance at the output point Tout on the amplifier circuit 170 side.

As illustrated in FIG. 4, the impedance conversion circuit 300 includes a transmission line transformer 310 and a capacitor 320 for cutting direct-current components.

The transmission line transformer 310 includes a transmission line 311 and a transmission line 312.

The transmission line 311 receives the signal RFg at a first end thereof electrically connected to the input point Tin3 through the capacitor 320. The transmission line 311 is electrically connected, at a second end thereof, to the amplifier circuit 170 through the output point Tout. The transmission line 311 is, for example, a quarter-wavelength or one-eighth wavelength line.

The transmission line 312 is electrically connected, at a first end thereof, to the second end of the transmission line 311, and is electrically connected, at a second end thereof, to a reference potential (for example, the ground). The transmission line 312 is electromagnetically coupled to the transmission line 311. The transmission line 312 is, for example, a quarter-wavelength or one-eighth wavelength line.

The transmission line transformer 310 is formed of transmission lines which are electromagnetically coupled to each other, achieving wideband impedance conversion. For example, the transmission line transformer 310 has a configuration which may implement impedance conversion of at least fundamental waves and second harmonic waves.

An overview example of the impedance conversion operation in the transmission line transformer 310 will be described.

An alternating current will be described. An alternating current flows from the first end to the second end of the transmission line 311. Then, an odd-mode current is induced from the second end to the first end of the transmission line 312. That is, a current in the transmission line 312 flows in the direction opposite to that of the alternating current flowing through the transmission line 311. When the magnitude of a current flowing to the input point Tin3 of the transmission line transformer 310 is represented by i, a current of 2i flows to the output point Tout.

Then, a voltage will be described. The voltage at the first end of the transmission line 311 is represented by v1; the voltage at the second end is represented by v2. The voltage at the input point Tin3 is equal to the voltage v1 at the first end of the transmission line 311. The voltage at the output point Tout is equal to the voltage v2 at the second end of the transmission line 311. The voltage at the first end of the transmission line 312 is also equal to the voltage v2 at the second end of the transmission line 311. The voltage at the second end of the transmission line 312 is 0 V. The potential difference (v2−v1) between the first end and the second end of the transmission line 311 is equal to the potential difference (0−v2) between the first end and the second end of the transmission line 312. Therefore, when this is solved, the voltage v2 at the output point Tout is half the voltage v1 at the input point Tin3 (v2=v½).

Then, in the transmission line transformer 310, when a load of impedance R is connected to the output point Tout, the expression, v2=2i×R, holds. When the impedance when the load side is viewed from the input point Tin3 is represented by R1, the expression, v1=R1×i, holds. When these expressions are solved, R1=4R is obtained. Thus, the impedance R1 when the load side is viewed from the input point Tin3 is four times the impedance R of the load connected to the output point Tout. Thus, the transmission line transformer 310 converts the impedance.

In the power amplifier circuit 100, the amplifier circuit 170 includes multiple transistors connected in parallel to one another. Thus, the input impedance of the amplifier circuit 170 is low. Regarding this point, the following situation occurs. Assume the case where an LC resonant circuit, which uses reflection, is used in the isolation circuit 200, which ensures isolation between the main path P1 and the secondary path P2 of the power amplifier circuit 100. In this case, to make the isolation circuit 200 operate appropriately so that the attenuation of fundamental waves and second harmonic waves sufficiently increases, the impedance of the LC resonant circuit at the resonant frequency needs to be sufficiently high or sufficiently low compared with the input impedance of the amplifier circuit 170. However, the LC resonant circuit has a finite parasitic resistance component. Therefore, when the input impedance of the amplifier circuit 170 is low, it is difficult to sufficiently decrease the impedance of the LC resonant circuit compared with the impedance of the amplifier circuit 170, resulting in inappropriate operation of the isolation circuit 200 in the power amplifier circuit.

Therefore, in the power amplifier circuit 100, the impedance conversion circuit 300, which includes the transmission line transformer 310, substantially increases the input impedance of the amplifier circuit 170. Thus, the power amplifier circuit 100 allows the isolation circuit 200 to appropriately operate so that isolation between the main path P1 and the secondary path P2 is ensured, achieving appropriate suppression of third-order inter-modulation distortion.

Further, in the power amplifier circuit 100, the wideband characteristics of the transmission line transformer cause a substantial increase of the input impedance of the amplifier circuit 170 for fundamental waves and second harmonic waves.

Thus, instead of, with simple use of a filter circuit, ensuring isolation between the main path P1 and the secondary path P2, the power amplifier circuit 100 uses a wideband transmission line transformer, which is applicable to the fundamental and second harmonic bands, to make the filter circuits of the isolation circuit 200 operate appropriately.

### First Modified Example

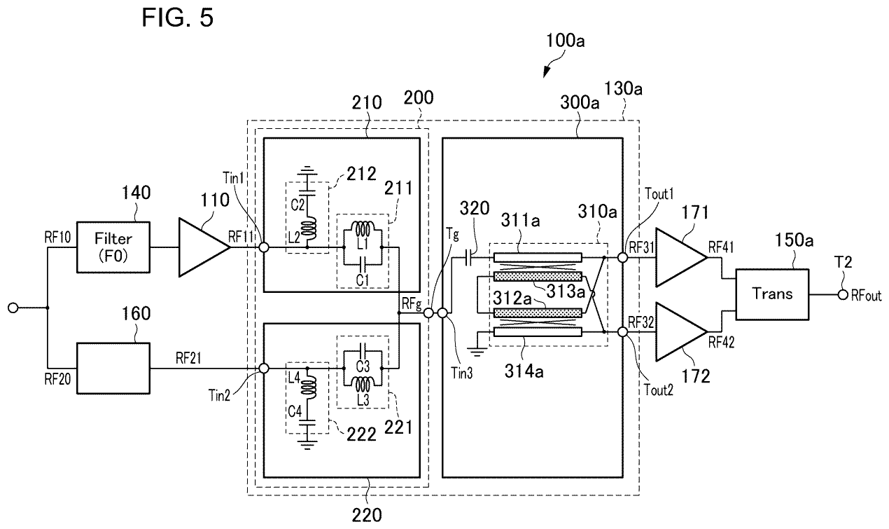

Referring to FIG. 5, a power amplifier circuit 100a according to a first modified example will be described. FIG. 5 is a diagram illustrating a configuration example of a combining circuit 130a of the power amplifier circuit 100a according to the first modified example. In the description below, only points different from those of the power amplifier circuit 100 will be described. Unless otherwise noted, the configuration is substantially the same as that of the power amplifier circuit 100.

The power amplifier circuit 100a is different from the power amplifier circuit 100 in that the amplifier circuit 170 is formed of a differential amplifier circuit. Accordingly, the combining circuit 130a includes an impedance conversion circuit 300a applicable to a differential amplifier circuit. The differential amplifier circuit includes an amplifier circuit 171 and an amplifier circuit 172.

The amplifier circuit 171 outputs, to a harmonic termination circuit 150a, a signal RF41 obtained by amplifying a signal RF31 outputted from the impedance conversion circuit 300a. The amplifier circuit 172 outputs, to the harmonic termination circuit 150a, a signal RF42 obtained by amplifying a signal RF32 which is outputted from the impedance conversion circuit 300a and which has a phase opposite to that of the signal RF31. The harmonic termination circuit 150a combines the signal RF41 with the signal RF42 to output, from the output terminal T2, the output signal RFout in which the second harmonic waves have been attenuated.

The impedance conversion circuit 300a divides the signal RFg, which is received from the isolation circuit 200, into the signal RF31 and the signal RF32, which have phases different by 180° from each other, for outputting to the differential amplifier circuit.

As illustrated in FIG. 5, the impedance conversion circuit 300a includes a transmission line transformer 310a and the capacitor 320 for DC cutting.

The transmission line transformer 310a includes a transmission line 311a, a transmission line 312a, a transmission line 313a, and a transmission line 314a. Each of the transmission lines 311a, 312a, 323a, and 314a is, for example, a quarter-wavelength line.

The transmission line 311a is electrically connected to the input point Tin3 through the capacitor 320 at a first end thereof where the signal RFg is received. The transmission line 311a is electrically connected, at a second end thereof, to the amplifier circuit 171 through an output point Tout1.

The transmission line 312a is electrically connected, at a first end thereof, to the second end of the transmission line 311a.

The transmission line 313a is electrically connected, at a first end thereof, to a second end of the transmission line 312a, and is electrically connected, at a second end thereof, to the amplifier circuit 172. The transmission line 313a is electromagnetically coupled to the transmission line 311a.

The transmission line 314a is electrically connected, at a first end thereof, to the second end of the transmission line 313a and also to the amplifier circuit 172 through an output point Tout2. The transmission line 314a is electrically connected, at a second end thereof, to a reference potential (for example, the ground). The transmission line 314a is electromagnetically coupled to the transmission line 312a.

The transmission line transformer 310a converts the impedance, and divides the signal RFg into the signal RF31 and the signal RF32 having a phase opposite to that of the signal RF31. The transmission line transformer 310a outputs the signal RF31 through the output point Tout1 to the amplifier circuit 171. The transmission line transformer 310a outputs the signal RF32 through the output point Tout2 to the amplifier circuit 172.

Thus, the power amplifier circuit 100a, which includes the differential amplifier circuit, improves high-frequency characteristics.

### Second Modified Example

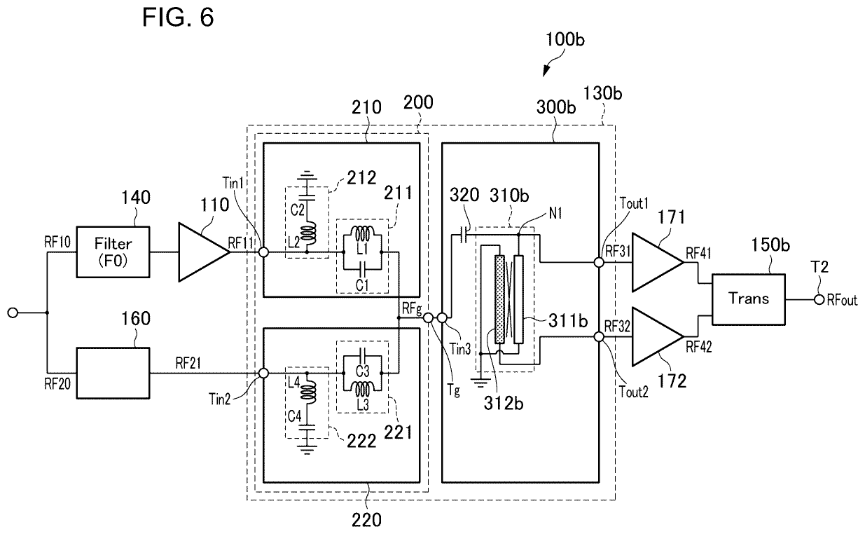

Referring to FIG. 6, a power amplifier circuit 100b according to a second modified example will be described. FIG. 6 is a diagram illustrating a configuration example of a combining circuit 130b of the power amplifier circuit 100b according to the second modified example. In the description below, only points different from those of the power amplifier circuit 100 will be described. Unless otherwise noted, the configuration is substantially the same as that of the power amplifier circuit 100.

The power amplifier circuit 100b is different from the power amplifier circuit 100 in that the amplifier circuit 170 is formed of a differential amplifier circuit. The combining circuit 130b includes an impedance conversion circuit 300b applicable to a differential amplifier circuit. The differential amplifier circuit includes the amplifier circuit 171 and the amplifier circuit 172.

The amplifier circuit 171 outputs, to a harmonic termination circuit 150b, the signal RF41 obtained by amplifying the signal RF31 outputted from the impedance conversion circuit 300b. The amplifier circuit 172 outputs, to the harmonic termination circuit 150b, the signal RF42 obtained by amplifying the signal RF32 which is outputted from the impedance conversion circuit 300c and which has a phase opposite to that of the signal RF31. The harmonic termination circuit 150b combines the signal RF41 with the signal RF42 to output, from the output terminal T2, the output signal RFout in which the second harmonic waves have been attenuated.

The impedance conversion circuit 300b divides the signal RFg, which is received from the isolation circuit 200, into the signal RF31 and the signal RF32, for outputting to the differential amplifier circuit.

As illustrated in FIG. 6, the impedance conversion circuit 300b includes a transmission line transformer 310b and the capacitor 320 for DC cutting. The capacitor 320 is connected in series between the input point Tin3 and the output point Tout1.

The transmission line transformer 310b includes a transmission line 311b and a transmission line 312b. Each of the transmission lines 311b and 312b is, for example, a quarter-wavelength line.

The transmission line 311b is electrically connected, at a first end thereof, to a node N1 between the input point Tin3 and the output point Tout1. The transmission line 311b is electrically connected, at the first end thereof, to the input point Tin3 through the capacitor 320.

The transmission line 312b is electrically connected, at a first end thereof, to a second end of the transmission line 311b, and is electrically connected, at a second end thereof, to the amplifier circuit 172 through the output point Tout2. The transmission line 312b is electromagnetically coupled to the transmission line 311b.

The transmission line transformer 310b converts the impedance, and divides the signal RFg into the signal RF31 and the signal RF32 having a phase opposite to that of the signal RF31. The transmission line transformer 310b outputs the signal RF31 to the amplifier circuit 171 through the output point Tout1. The transmission line transformer 310a outputs the signal RF32 to the amplifier circuit 172 through the output point Tout2.

Thus, the power amplifier circuit 100b, which includes the differential amplifier circuit, improves high-frequency characteristics. The power amplifier circuit 100b may have a transmission line transformer smaller than that of the power amplifier circuit 100a, achieving a reduction of circuit size.

### Third Modified Example

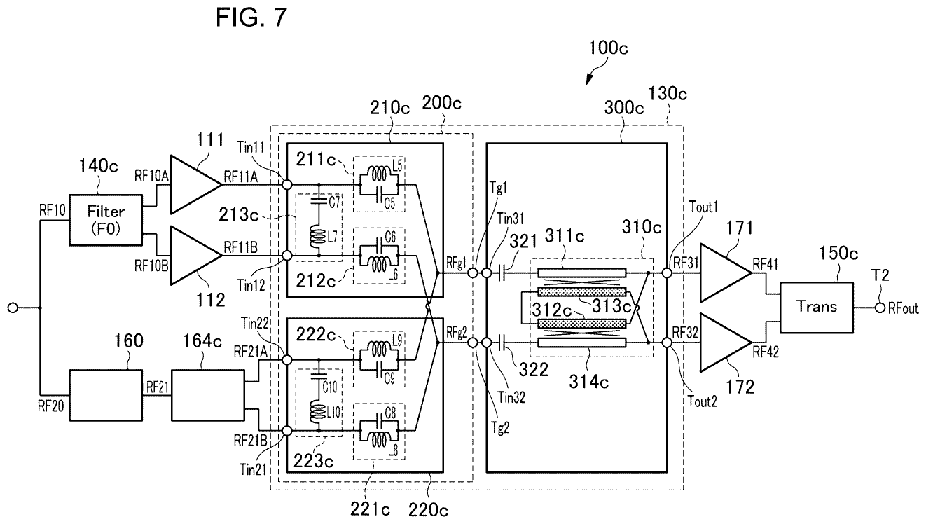

Referring to FIG. 7, a power amplifier circuit 100c according to a third modified example will be described. FIG. 7 is a diagram illustrating a configuration example of a combining circuit 130c of the power amplifier circuit 100c according to the third modified example. In the description below, only points different from those of the power amplifier circuit 100 will be described. Unless otherwise noted, the configuration is substantially the same as that of the power amplifier circuit 100.

The power amplifier circuit 100c is different from the power amplifier circuit 100 in that each of the amplifier circuit 110 and the amplifier circuit 170 of the power amplifier circuit 100 is formed of a differential amplifier circuit.

Accordingly, the power amplifier circuit 100c includes a divider 140c, which divides the signal RF10 into two signals having phases different by 180° from each other, a divider 164c, which divides the signal RF21 outputted from the distortion compensation circuit 160, and the combining circuit 130c compatible with the differential amplifier circuits.

The differential amplifier circuits include an amplifier circuit 111 and an amplifier circuit 112 in the driving stage, and include the amplifier circuit 171 and the amplifier circuit 172 in the power stage.

The divider 140c is, for example, a balun. The divider 140c divides the signal RF10 into a signal RF10A and a signal RF10B having a phase opposite to that of the signal RF10A. The divider 140c outputs the signal RF10A to the amplifier circuit 111, and outputs the signal RF10B to the amplifier circuit 112.

The amplifier circuit 111 outputs, to an input point Tin11 of an isolation circuit 200c, a signal RF11A obtained by amplifying the signal RF10A generated through the divider 140c's division of the signal RF10. The amplifier circuit 112 outputs, to an input point Tin12 of the isolation circuit 200c, a signal RF11B obtained by amplifying the signal RF10B which is generated through the divider 140c's division of the signal RF10 and which has a phase opposite to that of the signal RF10A.

The divider 164c is, for example, a balun. The divider 164c divides the signal RF21 into a signal RF21A and a signal RF21B having a phase opposite to that of the signal RF21A. The divider 164c outputs the signal RF21A to an input point Tin21 of the isolation circuit 200c, and outputs the signal RF21B to an input point Tin22 of the isolation circuit 200c.

The amplifier circuit 171 outputs, to a harmonic termination circuit 150c, the signal RF41 obtained by amplifying the signal RF31 outputted from an impedance conversion circuit 300c. The amplifier circuit 172 outputs, to the harmonic termination circuit 150c, the signal RF42 obtained by amplifying the signal RF32 which is outputted from the impedance conversion circuit 300c and which has a phase opposite to that of the signal RF31. The harmonic termination circuit 150c combines the signal RF41 with the signal RF42 to output, from the output terminal T2, the output signal RFout in which the second harmonic waves have been attenuated.

As illustrated in FIG. 7, the combining circuit 130c includes the isolation circuit 200c and the impedance conversion circuit 300c.

The isolation circuit 200c outputs, from a combination point Tg1, a signal RFg1 obtained by combining fundamental waves with second harmonic waves, and outputs a signal RFg2 from a combination point Tg2.

The isolation circuit 200c includes a second-harmonic attenuation unit 210c and a fundamental attenuation unit 220c.

The second-harmonic attenuation unit 210c is a circuit which receives the signal RF10A and the signal RF10B and which passes fundamental waves and attenuates second harmonic waves. The second-harmonic attenuation unit 210c includes a fifth filter circuit 211c, a sixth filter circuit 212c, and a seventh filter circuit 213c.

The fifth filter circuit 211c includes a capacitor C5 and an inductor L5 connected in parallel to each other. The fifth filter circuit 211c is electrically connected, at a first end thereof, to the input point Tin11 receiving the signal RF10A outputted from the amplifier circuit 111, and is electrically connected, at a second end thereof, to the combination point Tg1.

The sixth filter circuit 212c includes a capacitor C6 and an inductor L6 connected in parallel to each other. The sixth filter circuit 212c is electrically connected, at a first end thereof, to the input point Tin12 receiving the signal RF10B outputted from the amplifier circuit 112, and is electrically connected, at a second end thereof, to the combination point Tg2.

The seventh filter circuit 213c includes a capacitor C7 and an inductor L7 connected in series to each other. The seventh filter circuit 213c is electrically connected, at a first end thereof, to the first end of the fifth filter circuit 211c, and is electrically connected, at a second end thereof, to the first end of the sixth filter circuit 212c.

The fundamental attenuation unit 220c is a circuit which receives the signal RF21A and the signal RF21B and which passes second harmonic waves and attenuates fundamental waves. The fundamental attenuation unit 220c includes an eighth filter circuit 221c, a ninth filter circuit 222c, and a tenth filter circuit 223c.

The eighth filter circuit 221c includes a capacitor C8 and an inductor L8 connected in parallel to each other. The eighth filter circuit 221c is electrically connected, at a first end thereof, to the input point Tin21 receiving the signal RF21A outputted from the divider 164c, and is electrically connected, at a second end thereof, to the combination point Tg2.

The ninth filter circuit 222c includes a capacitor C9 and an inductor L9 connected in parallel to each other. The ninth filter circuit 222c is electrically connected, at a first end thereof, to the input point Tin22 receiving the signal RF21B outputted from the divider 164c, and is electrically connected, at a second end thereof, to the combination point Tg1.

The tenth filter circuit 223c includes a capacitor C10 and an inductor L10 connected in series to each other. The tenth filter circuit 223c is electrically connected, at a first end thereof, to the first end of the eighth filter circuit 221c, and is electrically connected, at a second end thereof, to the first end of the ninth filter circuit 222c.

The impedance conversion circuit 300c receives the signal RFg1 and the signal RFg2 from the isolation circuit 200c. On the basis of the signal RFg1 and the signal RFg2, the impedance conversion circuit 300c outputs the signal RF31 to the amplifier circuit 171, and outputs the signal RF32 to the amplifier circuit 172.

As illustrated in FIG. 7, the impedance conversion circuit 300c includes an input point Tin31, an input point Tin32, a transmission line transformer 310c, and capacitors 321 and 322 for DC cutting.

The input point Tin31 is electrically connected to the combination point Tg1 of the isolation circuit 200c. The input point Tin32 is electrically connected to the combination point Tg2 of the isolation circuit 200c.

The transmission line transformer 310c includes a transmission line 311c, a transmission line 312c, a transmission line 313c, and a transmission line 314c. Each of the transmission lines 311c, 312c, 323c, and 314a is, for example, a quarter-wavelength line.

The transmission line 311c is electrically connected to the input point Tin31 through the capacitor 321 at a first end thereof where the signal RFg1 is received. The transmission line 311c is electrically connected, at a second end thereof, to the amplifier circuit 171 through the output point Tout1.

The transmission line 312c is electrically connected, at a first end thereof, to the second end of the transmission line 311c.

The transmission line 313c is electrically connected, at a first end thereof, to a second end of the transmission line 312c, and is electrically connected, at a second end thereof, to the output point Tout2. The transmission line 313c is electromagnetically coupled to the transmission line 311c.

The transmission line 314c is electrically connected, at a first end thereof, to the second end of the transmission line 313c and also to the amplifier circuit 172 through the output point Tout2. The transmission line 314c is electrically connected to the input point Tin32 through the capacitor 322 at a second end thereof where the signal RFg2 is received. The transmission line 314c is electromagnetically coupled to the transmission line 312c.

The transmission line transformer 310c converts the impedance, and outputs the signal RF31 and the signal RF32, which has a phase opposite to that of the signal RF31, on the basis of the signal RFg1 and the signal RFg2. The transmission line transformer 310c outputs the signal RF31 to the amplifier circuit 171 through the output point Tout1. The transmission line transformer 310c outputs the signal RF32 to the amplifier circuit 172 through the output point Tout2.

Thus, the power amplifier circuit 100c, which includes the differential amplifier circuits in the driving stage and the power stage, improves high-frequency characteristics.

### Fourth Modified Example

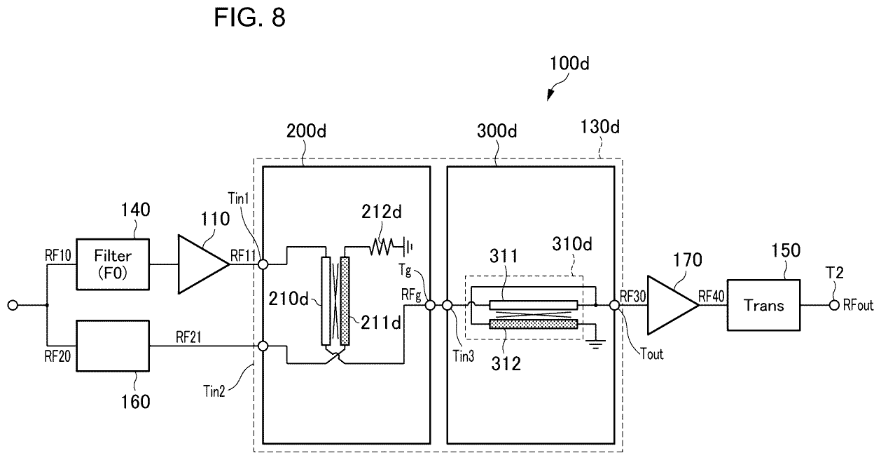

Referring to FIG. 8, a power amplifier circuit 100d according to a fourth modified example will be described. FIG. 8 is a diagram illustrating a configuration example of a combining circuit 130d of the power amplifier circuit 100d according to the fourth modified example. In the description below, only points different from those of the power amplifier circuit 100 will be described. Unless otherwise noted, the configuration is substantially the same as that of the power amplifier circuit 100.

The power amplifier circuit 100d is different from the power amplifier circuit 100 in that an isolation circuit 200d includes a 3-dB coupler. The power amplifier circuit 100d is different from the power amplifier circuit 100 in that an impedance conversion circuit 300d does not include a capacitor for DC cutting.

The isolation circuit 200d is, for example, a 3-dB coupler. The 3-dB coupler includes a line 210d, which serves as a second-harmonic attenuation unit, a line 211d, which serves as a fundamental attenuation unit, and a resistor 212d.

The line 210d is, for example, a quarter-wavelength line. The line 210d is electrically connected, at a first end thereof, to the input point Tin1, and is electrically connected, at a second end thereof, to the combination point Tg. The line 210d, which has characteristics equivalent to those of an inductor, passes fundamental waves of low frequency, and does not pass second harmonic waves of high frequency. That is, the line 210d has operational effect substantially the same as that of the second-harmonic attenuation unit 210 formed of filter circuits in the power amplifier circuit 100.

The line 211d is, for example, a quarter-wavelength line. The line 211d is electromagnetically coupled to the line 210d. The line 211d is electrically connected, at a first end thereof, to the input point Tin2, and is electrically connected, at a second end thereof, to a reference potential (for example, the ground) through the resistor 212d. The line 211d propagates second harmonic waves of high frequency to the line 210d, and does not propagate fundamental waves of low frequency to the line 210d. That is, the line 211d has operational effect substantially the same as that of the fundamental attenuation unit 220 in the power amplifier circuit 100.

The power amplifier circuit 100d includes the impedance conversion circuit 300d similar to the impedance conversion circuit 300 in the power amplifier circuit 100. In the power amplifier circuit 100d, the impedance conversion circuit 300d increasing the impedance on the isolation circuit 200d side of the impedance conversion circuit 300d allows the lines, which are included in the 3-dB coupler of the isolation circuit 200d, to have a small linewidth. Thus, the power amplifier circuit 100d achieves a reduction in size of circuit.

While the power amplifier circuit 100, which uses inductors and capacitors, causes operations to be affected in the case of high frequency due to self resonant frequency, the power amplifier circuit 100d, which uses transmission lines, is capable of performing high-frequency operations compared with the power amplifier circuit 100.

### Fifth Modified Example

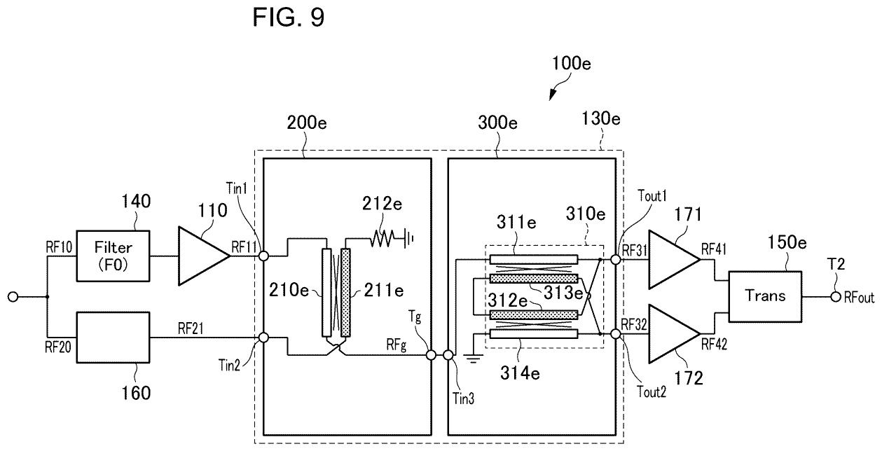

Referring to FIG. 9, a power amplifier circuit 100e according to a fifth modified example will be described. FIG. 9 is a diagram illustrating a configuration example of a combining circuit 130e of the power amplifier circuit 100e according to the fifth modified example. In the description below, only points different from those of the power amplifier circuit 100d in FIG. 8 will be described. Unless otherwise noted, the configuration is substantially the same as that of the power amplifier circuit 100 and the power amplifier circuit 100d.

The power amplifier circuit 100e is different from the power amplifier circuit 100d in that the amplifier circuit 170 is formed of a differential amplifier circuit. Accordingly, the combining circuit 130e includes an impedance conversion circuit 300e applicable to a differential amplifier circuit. The differential amplifier circuit includes the amplifier circuit 171 and the amplifier circuit 172. The amplifier circuit 171, the amplifier circuit 172, and a harmonic termination circuit 150e are substantially the same as the amplifier circuit 171, the amplifier circuit 172, and the harmonic termination circuit 150a of the power amplifier circuit 100a in FIG. 5, and will not be described.

The impedance conversion circuit 300e divides the signal RFg, which is received from an isolation circuit 200e, into the signal RF31 and the signal RF32, which have phases different by 180° from each other, for outputting to the differential amplifier circuit.

As illustrated in FIG. 9, the impedance conversion circuit 300e includes a transmission line transformer 310e and the capacitor 320 for DC cutting.

The transmission line transformer 310e includes a transmission line 311e, a transmission line 312e, a transmission line 313e, and a transmission line 314e. Each of the transmission lines 311e, 312e, 323e, and 314e is, for example, a quarter-wavelength line. The electrical connection relationship of the transmission lines 311e, 312e, 323e, and 314e is substantially the same as that of the transmission lines 311a, 312a, 323a, and 314a in FIG. 5, and will not be described.

The transmission line transformer 310e converts the impedance and divides the signal RFg into the signal RF31 and the signal RF32 having a phase opposite to that of the signal RF31. The transmission line transformer 310e outputs the signal RF31 to the amplifier circuit 171 through the output point Tout1. The transmission line transformer 310e outputs the signal RF32 to the amplifier circuit 172 through the output point Tout2.

Thus, the power amplifier circuit 100e, which includes the differential amplifier circuit, improves high-frequency characteristics.

### Sixth Modified Example

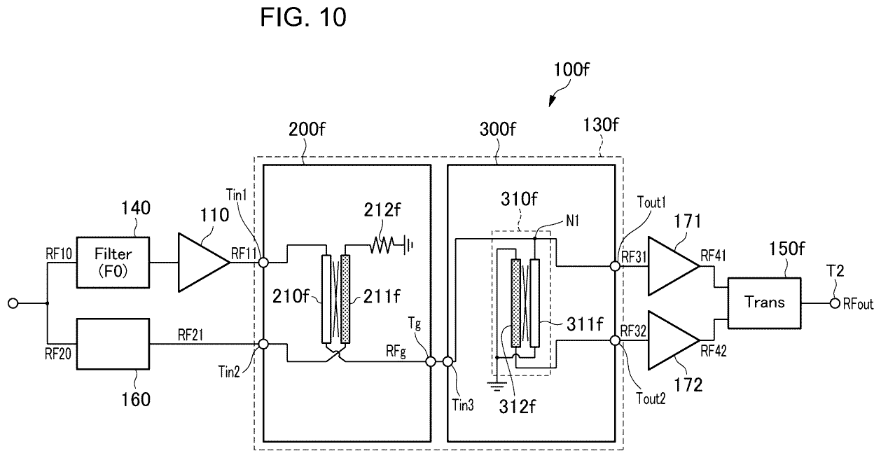

Referring to FIG. 10, a power amplifier circuit 100f according to a sixth modified example will be described. FIG. 10 is a diagram illustrating a configuration example of a combining circuit 130f of the power amplifier circuit 100f according to the sixth modified example. In the description below, only points different from those of the power amplifier circuit 100d in FIG. 8 will be described. Unless otherwise noted, the configuration is substantially the same as that of the power amplifier circuit 100 and the power amplifier circuit 100d.

The power amplifier circuit 100f is different from the power amplifier circuit 100d in that the amplifier circuit 170 is formed of a differential amplifier circuit. Accordingly, the combining circuit 130f includes an impedance conversion circuit 300f applicable to a differential amplifier circuit. The differential amplifier circuit includes the amplifier circuit 171 and the amplifier circuit 172. The amplifier circuit 171, the amplifier circuit 172, and a harmonic termination circuit 150f are substantially the same as the amplifier circuit 171, the amplifier circuit 172, and the harmonic termination circuit 150b of the power amplifier circuit 100b in FIG. 6, and will not be described.

The impedance conversion circuit 300f divides the signal RFg, which is received from an isolation circuit 200f, into the signal RF31 and the signal RF32, which have phases different by 180° from each other, for outputting to the differential amplifier circuit.

As illustrated in FIG. 10, the impedance conversion circuit 300f includes a transmission line transformer 310f and the capacitor 320 for DC cutting.

The transmission line transformer 310f includes a transmission line 311f and a transmission line 312f. Each of the transmission lines 311f and 312f is, for example, a quarter-wavelength line. The electrical connection relationship of the transmission lines 311f and 312f is substantially the same as that of the transmission lines 311b and 312b in FIG. 6, and will not be described.

The transmission line transformer 310f converts the impedance and divides the signal RFg into the signal RF31 and the signal RF32 having a phase opposite to that of the signal RF31. The transmission line transformer 310f outputs the signal RF31 to the amplifier circuit 171 through the output point Tout1. The transmission line transformer 310f outputs the signal RF32 to the amplifier circuit 172 through the output point Tout2.

Thus, the power amplifier circuit 100f, which includes the differential amplifier circuit, improves high-frequency characteristics. The power amplifier circuit 100f may have a transmission line transformer smaller than that of the power amplifier circuit 100e, achieving a reduction of circuit size.

### Seventh Modified Example

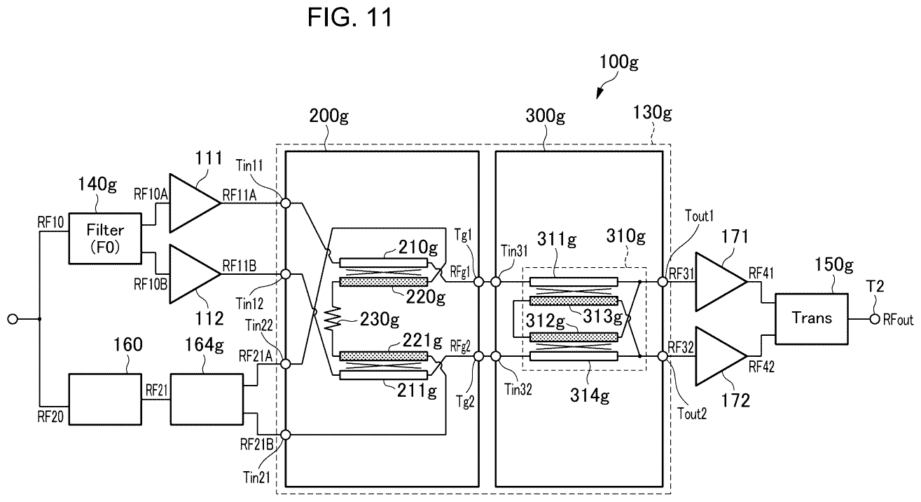

Referring to FIG. 11, a power amplifier circuit 100g according to a seventh modified example will be described. FIG. 11 is a diagram illustrating a configuration example of a combining circuit 130g of the power amplifier circuit 100g according to the seventh modified example. In the description below, only points different from those of the power amplifier circuit 100d in FIG. 8 will be described. Unless otherwise noted, the configuration is substantially the same as that of the power amplifier circuit 100d.

The power amplifier circuit 100g is different from the power amplifier circuit 100d in that each of the amplifier circuit 110 and the amplifier circuit 170 of the power amplifier circuit 100d is formed of a differential amplifier circuit.

Accordingly, the power amplifier circuit 100g includes a divider 140g, which divides the signal RF10 into two signals having phases different by 180° from each other, a divider 164g, which divides the signal RF21 outputted from the distortion compensation circuit 160, and the combining circuit 130g compatible with the differential amplifier circuits.

The differential amplifier circuits include the amplifier circuit 111 and the amplifier circuit 112 in the driving stage, and include the amplifier circuit 171 and the amplifier circuit 172 in the power stage.

The divider 140g is, for example, a balun. The divider 140g divides the signal RF10 into the signal RF10A and the signal RF10B having a phase opposite to that of the signal RF10A. The divider 140g outputs the signal RF10A to the amplifier circuit 111, and outputs the signal RF10B to the amplifier circuit 112.

The amplifier circuit 111 outputs, to the input point Tin11 of an isolation circuit 200g, the signal RF11A obtained by amplifying the signal RF10A generated through the divider 140g's division of the signal RF10. The amplifier circuit 112 outputs, to the input point Tin12 of the isolation circuit 200g, the signal RF11B obtained by amplifying the signal RF10B which is generated through the divider 140g's division of the signal RF10 and which has a phase opposite to that of the signal RF10A.

The divider 164g is, for example, a balun. The divider 164g divides the signal RF21 into the signal RF21A and the signal RF21B having a phase opposite to that of the signal RF21A. The divider 164g outputs the signal RF21A to the input point Tin21 of the isolation circuit 200c, and outputs the signal RF21B to the input point Tin22 of the isolation circuit 200c.

The amplifier circuit 171 outputs, to a harmonic termination circuit 150g, the signal RF41 obtained by amplifying the signal RF31 outputted from an impedance conversion circuit 300g. The amplifier circuit 172 outputs, to the harmonic termination circuit 150g, the signal RF42 obtained by amplifying the signal RF32 which is outputted from the impedance conversion circuit 300g and which has a phase opposite to that of the signal RF31. The harmonic termination circuit 150g combines the signal RF31 with the signal RF32, and outputs, from the output terminal T2, the output signal RFout in which the second harmonic waves have been attenuated.

As illustrated in FIG. 11, the combining circuit 130g includes the isolation circuit 200g and the impedance conversion circuit 300g.

The isolation circuit 200g outputs, from the combination point Tg1, the signal RFg1 obtained by combining the fundamental waves with the second harmonic waves, and outputs the signal RFg2 from the combination point Tg2.

The isolation circuit 200c includes a line 210g and a line 211g, which serve as a second-harmonic attenuation unit, and a line 220g and a line 221g, which serve as a fundamental attenuation unit, and a resistor 230g.

The line 210g is, for example, a quarter-wavelength line. The line 210g is electrically connected, at a first end thereof, to the input point Tin11, and is electrically connected, at a second end thereof, to the combination point Tg1. The line 210g, which has characteristics equivalent to those of an inductor, passes fundamental waves of low frequency, and does not pass second harmonic waves of high frequency. That is, the line 210g has operational effect substantially the same as that of the second-harmonic attenuation unit 210 formed of filter circuits in the power amplifier circuit 100.

The line 211g is, for example, a quarter-wavelength line. The line 211g is electrically connected, at a first end thereof, to the input point Tin12, and is electrically connected, at a second end thereof, to the combination point Tg2. The line 211g, which has characteristics equivalent to those of an inductor, passes fundamental waves of low frequency, and does not pass second harmonic waves of high frequency. That is, the line 211g has operational effect substantially the same as that of the second-harmonic attenuation unit 210 formed of filter circuits in the power amplifier circuit 100.

The line 220g is, for example, a quarter-wavelength line. The line 220g is electromagnetically coupled to the line 210g. The line 220g is electrically connected, at a first end thereof, to the input point Tin22. The line 220g causes second harmonic waves of high frequency to propagate to the line 210g, and does not cause fundamental waves of low frequency to propagate to the line 210g. That is, the line 220g has operational effect substantially the same as that of the fundamental attenuation unit 220 of the power amplifier circuit 100.

The line 221g is, for example, a quarter-wavelength line. The line 221g is electromagnetically coupled to the line 211g. The line 221g is electrically connected, at a first end thereof, to the input point Tin21, and is electrically connected, at a second end thereof, to a second end of the line 220g through the resistor 230g. The line 221g causes second harmonic waves of high frequency to propagate to the line 211g, and does not cause fundamental waves of low frequency to propagate to the line 211g. That is, the line 221g has operational effect substantially the same as that of the fundamental attenuation unit 220 of the power amplifier circuit 100.

The impedance conversion circuit 300g receives the signal RFg1 and the signal RFg2 from the isolation circuit 200g. On the basis of the signal RFg1 and the signal RFg2, the impedance conversion circuit 300g outputs the signal RF31 to the amplifier circuit 171, and outputs the signal RF32 to the amplifier circuit 172.

As illustrated in FIG. 11, the impedance conversion circuit 300g includes the input point Tin31, the input point Tin32, and a transmission line transformer 310g.

The input point Tin31 is electrically connected to the combination point Tg1 of the isolation circuit 200g. The input point Tin32 is electrically connected to the combination point Tg2 of the isolation circuit 200g.

The transmission line transformer 310g includes a transmission line 311g, a transmission line 312g, a transmission line 313g, and a transmission line 314g. Each of the transmission lines 311g, 312g, 323g, and 314g is, for example, a quarter-wavelength line.

The transmission line 311g is electrically connected, at a first end thereof, to the input point Tin31, and receives the signal RFg1. The transmission line 311g is electrically connected, at a second end thereof, to the amplifier circuit 171 through the output point Tout1.

The transmission line 312g is electrically connected, at a first end thereof, to the second end of the transmission line 311c.

The transmission line 313g is electrically connected, at a first end thereof, to a second end of the transmission line 312g, and is electrically connected, at a second end thereof, to the output point Tout2. The transmission line 313g is electromagnetically coupled to the transmission line 311g.

The transmission line 314g is electrically connected, at a first end thereof, to the second end of the transmission line 313g and also to the amplifier circuit 172 through the output point Tout2. The transmission line 314g is electrically connected to the input point Tin32 at a second end thereof where the signal RFg2 is received. The transmission line 314g is electromagnetically coupled to the transmission line 312g.

The transmission line transformer 310g converts the impedance, and outputs the signal RF31 and the signal RF32, which has a phase opposite to that of the signal RF31, on the basis of the signal RFg1 and the signal RFg2. The transmission line transformer 310c outputs the signal RF31 to the amplifier circuit 171 through the output point Tout1. The transmission line transformer 310c outputs the signal RF32 to the amplifier circuit 172 through the output point Tout2.

Thus, the power amplifier circuit 100a, which includes the differential amplifier circuits in the driving stage and the power stage, improves high-frequency characteristics.

### CONCLUSION

<1> The power amplifier circuit 100 includes the isolation circuit 200, the impedance conversion circuit 300, and the amplifier circuit 170. The isolation circuit 200 includes the second-harmonic attenuation unit 210 and the fundamental attenuation unit 220. The second-harmonic attenuation unit 210 receives the signal RF10 (first signal) obtained through division of the input signal RFin, and passes fundamental waves of the signal RF10 (first signal) and attenuates second harmonic waves of the signal RF10 (first signal). The fundamental attenuation unit 220 receives the signal RF20 (second signal) obtained through division of the input signal RFin, and passes second harmonic waves of the signal RF20 (second signal) and attenuates fundamental waves of the signal RF20 (second signal). The isolation circuit 200 outputs, from the combination point Tg, the signal RFg (combined signal) obtained by combining the signal RF10 (first signal), which has passed through the second-harmonic attenuation unit 210, with the signal RF20 (second signal), which has passed through the fundamental attenuation unit 220. The impedance conversion circuit 300 receives the signal RFg (combined signal) at the input point Tin3, outputs, from the output point Tout, the signal RF30 (output combined signal) obtained through impedance conversion of the signal RFg (combined signal), and includes the transmission line transformer 310. The impedance conversion circuit 300 performs the impedance conversion to make the impedance at the input point Tin3 larger than that at the output point Tout. The amplifier circuit 170 amplifies the signal RFg (combined signal) to output the signal RF40 (amplified signal). Thus, the power amplifier circuit 100, which uses the wideband transmission line transformer 310, may ensure isolation between the main path P1, through which fundamental waves pass, and the secondary path P2, through which second harmonic waves pass, achieving appropriate suppression of third-order inter-modulation distortion.
<2> The power amplifier circuit 100, in the power amplifier circuit according to <1>, the transmission line transformer 310 of the impedance conversion circuit 300 includes the transmission line 311 (first transmission line) and the transmission line 312 (second transmission line). The transmission line 311 (first transmission line) receives the signal RFg (combined signal) at the first end thereof electrically connected to the input point Tin3, and is electrically connected to the amplifier circuit 170 at the second end thereof electrically connected to the output point Tout. The transmission line 312 (second transmission line) is electrically connected, at the first end thereof, to the second end of the transmission line 311 (first transmission line), and is electrically connected, at the second end thereof, to the reference potential. The transmission line 312 (second transmission line) is electromagnetically coupled to the transmission line 311 (first transmission line). Thus, the power amplifier circuit 100, which uses the wideband transmission line transformer 310, may ensure isolation between the main path P1, through which fundamental waves pass, and the secondary path P2, through which second harmonic waves pass, achieving appropriate suppression of third-order inter-modulation distortion.
<3> According to the power amplifier circuit 100a, in the power amplifier circuit according to <1>, the amplifier circuit 170 includes the amplifier circuit 171 (first amplifier circuit) and the amplifier circuit 172 (second amplifier circuit) to form a differential amplifier circuit. The impedance conversion circuit 300a divides the signal RFg (combined signal) into the signal RF31 (first division signal) and the signal RF32 (second division signal) having a phase opposite to that of the signal RF31 (first division signal). The impedance conversion circuit 300a outputs the signal RF31 (first division signal) to the amplifier circuit 171 (first amplifier circuit) from the output point Tout1 (first output point) of the output point Tout. The impedance conversion circuit 300a outputs the signal RF32 (second division signal) to the amplifier circuit 172 (second amplifier circuit) from the output point Tout2 (second output point) of the output point Tout. The transmission line transformer 310 includes the transmission line 311a (third transmission line), the transmission line 312a (fourth transmission line), the transmission line 313a (fifth transmission line), and the transmission line 314a (sixth transmission line). The transmission line 311a (third transmission line) receives the signal RFg (combined signal) at the first end thereof electrically connected to the input point Tin3, and is electrically connected to the amplifier circuit 171 (first amplifier circuit) at the second end thereof electrically connected to the output point Tout1 (first output point). The transmission line 312a (fourth transmission line) is electrically connected, at the first end thereof, to the second end of the transmission line 311a (third transmission line). The transmission line 313a (fifth transmission line) is electrically connected, at the first end thereof, to the second end of the transmission line 312a (fourth transmission line), and is electrically connected, at the second end thereof, to the amplifier circuit 172 (second amplifier circuit). The transmission line 313a (fifth transmission line) is electromagnetically coupled to the transmission line 311a (third transmission line). The transmission line 314a (sixth transmission line) is electrically connected to the second end of the transmission line 313a (fifth transmission line) at the first end thereof electrically connected to the output point Tout2 (second output point), and is electrically connected, at the second end thereof, to the reference potential. The transmission line 314a (sixth transmission line) is electromagnetically coupled to the transmission line 312a (fourth transmission line). Thus, the power amplifier circuit 100a, which ensures isolation and includes the differential amplifier circuit, improves high-frequency characteristics, achieving more appropriate suppression of third-order inter-modulation distortion.
<4> According to the power amplifier circuit 100b, in the power amplifier circuit according to <1>, the amplifier circuit 170 includes the amplifier circuit 171 (first amplifier circuit) and the amplifier circuit 172 (second amplifier circuit) to form a differential amplifier circuit. The impedance conversion circuit 300b divides the signal RFg (combined signal) into the signal RF31 (first division signal) and the signal RF32 (second division signal) having a phase opposite to that of the signal RF31 (first division signal). The impedance conversion circuit 300b outputs the signal RF31 (first division signal) to the amplifier circuit 171 (first amplifier circuit) from the output point Tout1 (first output point) of the output point Tout. The impedance conversion circuit 300b outputs the signal RF32 (second division signal) to the amplifier circuit 172 (second amplifier circuit) from the output point Tout2 (second output point) of the output point Tout. The transmission line transformer 310 includes the transmission line 311b (seventh transmission line) and the transmission line 312b (eighth transmission line). The transmission line 311b (seventh transmission line) is electrically connected, at the first end thereof, to the node N1 between the input point Tin3 and the output point Tout1 (first output point), and is electrically connected, at the second end thereof, to the reference potential. The transmission line 312b (eighth transmission line) is electrically connected, at the first end thereof, to the second end of the transmission line 311b (seventh transmission line), and is electrically connected, at the second end thereof, to the output point Tout2 (second output point). The transmission line 312b (eighth transmission line) is electromagnetically coupled to the transmission line 311b (seventh transmission line). Thus, the power amplifier circuit 100b, which ensures isolation and includes the differential amplifier circuit, improves high-frequency characteristics, achieving more appropriate suppression of third-order inter-modulation distortion. Further, the power amplifier circuit 100b may have a transmission line transformer smaller than that of the power amplifier circuit 100a, achieving a reduction of circuit size.
<5> According to the power amplifier circuit 100, in the power amplifier circuit according to any one of <1> to <4>, in the isolation circuit 200, the second-harmonic attenuation unit 210 includes the first filter circuit 211 and the second filter circuit 212. The first filter circuit 211 is connected in series between the combination point Tg and the input point Tin1 (first input point) receiving the signal RF10 (first signal), and includes the capacitor C1 (first capacitor) and the inductor L1 (first inductor) which are connected in parallel to each other. The second filter circuit 212 is connected in series between the reference potential and a node between the input point Tin1 (first input point) and the combination point Tg, and includes the capacitor C2 (second capacitor) and the inductor L2 (second inductor) which are connected in series to each other. The fundamental attenuation unit 220 includes the third filter circuit 221 and the fourth filter circuit 222. The third filter circuit 221 is connected in series between the combination point Tg and the input point Tin2 (second input point) receiving the signal RF20 (second signal), and includes the capacitor C3 (third capacitor) and the inductor L4 (third inductor) connected in parallel to each other. The fourth filter circuit 222 is connected in series between the reference potential and a node between the input point Tin2 (second input point) and the combination point Tg, and includes the capacitor C4 (fourth capacitor) and the inductor L4 (fourth inductor) connected in series to each other. Thus, the power amplifier circuit 100 may ensure isolation between the main path P1, through which fundamental waves pass, and the secondary path P2, through which second harmonic waves pass, with a simple configuration.
<6> According to the power amplifier circuit 100d (including the power amplifier circuit 100e, 100f), in the power amplifier circuit according to any one of <1> to <4>, in the isolation circuit 200, the second-harmonic attenuation unit 210 includes the line 210d (first line) which is electrically connected, at the first end thereof, to the input point Tin1 (first input point) receiving the signal RF10 (first signal), and which is connected, at the second end thereof, to the combination point Tg. The fundamental attenuation unit 220 includes the line 211d (second line) which is electrically connected, at the first end thereof, to the input point Tin2 (second input point) receiving the signal RF20 (second signal), and which is electrically connected, at the second end thereof, to the reference potential. The line 211d (second line) is electromagnetically coupled to the line 210d (first line). Thus, the power amplifier circuit 100d may cause isolation between the main path P1, through which fundamental waves pass, and the secondary path P2, through which second harmonic waves pass, with a simple configuration to be ensured. The power amplifier circuit 100d, which includes the isolation circuit formed of the transmission line transformer, does not receive any influence, on operation, which occurs in the case of high frequency due to self resonant frequency, achieving high-frequency operation compared with the power amplifier circuit 100.
<7> According to the power amplifier circuit 100c, in the power amplifier circuit according to <1>, in the isolation circuit 200, the second-harmonic attenuation unit 210 includes the fifth filter circuit 211c, the sixth filter circuit 212c, and the seventh filter circuit 213c. The fifth filter circuit 211c is connected, at the first end thereof, in series to the input point Tin11 (third input point) receiving the signal RF10A (first differential signal) obtained through division of the signal RF10 (first signal), and includes the capacitor C5 (fifth capacitor) and the inductor L5 (fifth inductor) which are connected in parallel to each other. The sixth filter circuit 212c is connected, at the first end thereof, in series to the input point Tin12 (fourth input point) receiving the signal RF10B (second differential signal) which has a phase opposite to that of the signal RF10A (first differential signal) and which is obtained through division of the signal RF10 (first signal), and includes the capacitor C6 (sixth capacitor) and the inductor L (sixth inductor) which are connected in parallel to each other. The seventh filter circuit 213c is electrically connected, at the first end thereof, to the first end of the fifth filter circuit 211c, and is electrically connected, at the second end thereof, to the first end of the sixth filter circuit 212c. The seventh filter circuit 213c includes the capacitor C7 (seventh capacitor) and the inductor L7 (seventh inductor) which are connected in series to each other. The fundamental attenuation unit 220 includes the eighth filter circuit 221c, the ninth filter circuit 222c, and the tenth filter circuit 223c. The eighth filter circuit 221c is connected, at the first end thereof, in series to the input point Tin21 (fifth input point) receiving the signal RF21A (third differential signal) obtained through division of the signal RF20 (second signal), and includes the capacitor C8 (eighth capacitor) and the inductor L8 (eighth inductor) which are connected in parallel to each other. The ninth filter circuit 222c is connected, at the first end thereof, in series to the input point Tin22 (sixth input point) receiving the signal RF21B (fourth differential signal) which has a phase opposite to that of the signal RF21A (third differential signal) and which is obtained through division of the signal RF20 (second signal), and includes the capacitor C9 (ninth capacitor) and the inductor L9 (ninth inductor) which are connected in parallel to each other. The tenth filter circuit 223c is electrically connected, at the first end thereof, to the first end of the eighth filter circuit 221c, and is electrically connected, at the second end thereof, to the first end of the ninth filter circuit 222c. The tenth filter circuit 223c includes the capacitor C10 (tenth capacitor) and the inductor L10 (tenth inductor) which are connected in series to each other. The first combination point Tg1 of the combination point Tg is electrically connected to the second end of the fifth filter circuit 211c and the second end of the eighth filter circuit 221c. The second combination point Tg2 of the combination point Tg is electrically connected to the second end of the sixth filter circuit 212c and the second end of the ninth filter circuit 222c. The amplifier circuit 170 includes the amplifier circuit 171 (first amplifier circuit) and the amplifier circuit 172 (second amplifier circuit) to form a differential amplifier circuit. The impedance conversion circuit 300c outputs the signal RF31 (first division signal) from the output point Tout1 (first output point) of the output point Tout to the amplifier circuit 171 (first amplifier circuit). The impedance conversion circuit 300c outputs the signal RF32 (second division signal), which has a phase opposite to that of the signal RF31 (first division signal), from the output point Tout2 (second output point) of the output point Tout to the amplifier circuit 172 (second amplifier circuit). The transmission line transformer 310 includes the transmission line 311c (eleventh transmission line), the transmission line 312c (twelfth transmission line), the transmission line 313c (thirteenth transmission line), and the transmission line 314c (fourteenth transmission line). The transmission line 311c (eleventh transmission line) is electrically connected, at the first end thereof, to the combination point Tg1 (first combination point), and is electrically connected to the amplifier circuit 171 (first amplifier circuit) at the second end thereof electrically connected to the output point Tout1 (first output point). The transmission line 312c (twelfth transmission line) is electrically connected, at the first end thereof, to the second end of the transmission line 311c (eleventh transmission line). The transmission line 313c (thirteenth transmission line) is electrically connected, at the first end thereof, to the second end of the transmission line 312c (twelfth transmission line), and is electrically connected, at the second end thereof, to the amplifier circuit 172 (second amplifier circuit). The transmission line 313c (thirteenth transmission line) is electromagnetically coupled to the transmission line 311c (eleventh transmission line). The transmission line 314c (fourteenth transmission line) is electrically connected to the second end of the transmission line 313c (thirteenth transmission line) at the first end thereof electrically connected to the output point Tout2 (second output point), and is electrically connected, at the second end thereof, to the combination point Tg2 (second combination point). The transmission line 314c (fourteenth transmission line) is electromagnetically coupled to the transmission line 312c (twelfth transmission line). Thus, the power amplifier circuit 100c, which includes the differential amplifier circuits in the driving stage and the power stage, improves high-frequency characteristics.
<8> According to the power amplifier circuit 100g, in the power amplifier circuit according to <1>, in the isolation circuit 200, the second-harmonic attenuation unit 210 includes the line 210g (third line) and the line 211g (fourth line). The line 210g (third line) is electrically connected, at the first end thereof, to the input point Tin11 (third input point) receiving the signal RF10A (first differential signal) obtained through division of the signal RF10 (first signal). The line 211g (fourth line) is electrically connected, at the first end thereof, to the input point Tin12 (fourth input point) receiving the signal RF10B (second differential signal) which has a phase opposite to that of the signal RF10A (first differential signal) obtained through division of the signal RF10 (first signal). The fundamental attenuation unit 220 includes the line 220g (fifth line) and the line 221g (sixth line). The line 220g (fifth line) is electrically connected, at the first end thereof, to the input point Tin21 (fifth input point) receiving the signal RF21A (third differential signal) obtained through division of the signal RF20 (second signal), and is electromagnetically coupled to the line 210g (third line). The line 221g (sixth line) is electrically connected, at the first end thereof, to the input point Tin22 (sixth input point) receiving the signal RF21B (fourth differential signal) having a phase opposite to that of the signal RF21A (third differential signal) obtained through division of the signal RF20 (second signal), and is electrically connected, at the second end thereof, to the second end of the line 220g (fifth line) through a resistor. The line 221g (sixth line) is electromagnetically coupled to the line 211g (fourth line). The combination point Tg1 (first combination point) of the combination point Tg is electrically connected to the second end of the line 210g (third line). The combination point Tg2 (second combination point) of the combination point Tg is electrically connected to the second end of the line 211g (fourth line). The amplifier circuit 170 includes the amplifier circuit 171 (first amplifier circuit) and the amplifier circuit 172 (second amplifier circuit) to form a differential amplifier circuit. The impedance conversion circuit 300g outputs the signal RF31 (first division signal) to the amplifier circuit 171 (first amplifier circuit) from the output point Tout1 (first output point) of the output point Tout, and outputs the signal RF32 (second division signal), which has a phase opposite to that of the signal RF31 (first division signal), from the output point Tout2 (second output point) of the output point Tout to the amplifier circuit 172 (second amplifier circuit). The impedance conversion circuit 300g includes the transmission line 311g (fifteenth transmission line), the transmission line 312g (sixteenth transmission line), the transmission line 313g (seventeenth transmission line), and the transmission line 314g (eighteenth transmission line). The transmission line 311g (fifteenth transmission line) is electrically connected, at the first end thereof, to the combination point Tg1 (first combination point), and is electrically connected, at the second end thereof which is the output point Tout1 (first output point), to the amplifier circuit 171 (first amplifier circuit). The transmission line 312g (sixteenth transmission line) is electrically connected, at the first end thereof, to the second end of the transmission line 311g (fifteenth transmission line). The transmission line 313g (seventeenth transmission line) is electrically connected, at the first end thereof, to the second end of the transmission line 312g (sixteenth transmission line), and is electrically connected, at the second end thereof, to the amplifier circuit 172 (second amplifier circuit). The transmission line 313g (seventeenth transmission line) is electromagnetically coupled to the transmission line 311g (fifteenth transmission line). The transmission line 314g (eighteenth transmission line) is electrically connected, at the first end thereof which is the output point Tout2 (second output point), to the second end of the transmission line 313g (seventeenth transmission line), and is electrically connected, at the second end thereof, to the combination point Tg2 (second combination point). The transmission line 314g (eighteenth transmission line) is electromagnetically coupled to the transmission line 312g (sixteenth transmission line). Thus, the power amplifier circuit 100g, which includes the differential amplifier circuits in the driving stage and the power stage, improves high-frequency characteristics.

The embodiments described above are made to facilitate understanding of the present disclosure, not to interpret the present disclosure limitedly. The present disclosure may be changed/improved without departing from the gist thereof, and the equivalents are encompassed in the present disclosure. That is, embodiments obtained by those skilled in the art adding changes appropriately to the embodiments are encompassed in the scope of the present disclosure as long as having features of the present disclosure. For example, the components included in the embodiments and their layouts, materials, conditions, shapes, sizes, and the like are not limited to illustrated ones, and may be changed appropriately. Components included in the embodiments may be combined with each other as far as technically possible. These combinations are also encompassed in the scope of the present disclosure as long as having features of the present disclosure.

What is claimed is:

1. A power amplifier circuit comprising:
an isolation circuit that comprises:
a second-harmonic attenuation circuit which receives a first signal obtained through division of an input signal, and which is configured to pass a fundamental wave of the first signal and attenuate a second harmonic wave of the first signal, and
a fundamental attenuation circuit which receives a second signal obtained through division of the input signal, and which is configured to pass a second harmonic wave of the second signal and attenuate a fundamental wave of the second signal,
the isolation circuit being configured to output, from a combination point thereof, a combined signal obtained by combining the first signal having passed through the second-harmonic attenuation circuit, with the second signal having passed through the fundamental attenuation circuit;
an impedance conversion circuit that receives, at an input point thereof, the combined signal, and that is configured to output, from an output point thereof, an output combined signal obtained through impedance conversion of the combined signal, the impedance conversion circuit comprising a transmission line transformer and being configured to perform impedance conversion such that an impedance at the input point larger than an impedance at the output point; and
an amplifier circuit configured to amplify the combined signal and output an amplified signal.

2. The power amplifier circuit according to claim 1, wherein the transmission line transformer of the impedance conversion circuit comprises:
a first transmission line that receives the combined signal at a first end thereof electrically connected to the input point, and that is electrically connected to the amplifier circuit and to the output point of the impedance conversion circuit at a second end thereof, and
a second transmission line that is electrically connected at a first end thereof to the second end of the first transmission line, and that is electrically connected at a second end thereof to a reference potential, the second transmission line being electromagnetically coupled to the first transmission line.

3. The power amplifier circuit according to claim 1,
wherein the amplifier circuit comprises a first amplifier circuit and a second amplifier circuit that form a differential amplifier circuit,
wherein the impedance conversion circuit is configured to:
divide the combined signal into a first division signal and a second division signal, the second division signal having a phase opposite to a phase of the first division signal,
output the first division signal to the first amplifier circuit from a first output node of the output point, and
output the second division signal to the second amplifier circuit from a second output node of the output point, and
wherein the transmission line transformer comprises:
a third transmission line that receives the combined signal at a first end thereof electrically connected to the input point, and that is electrically connected to the first amplifier circuit and to the first output node at a second end thereof;
a fourth transmission line that is electrically connected at a first end thereof to the second end of the third transmission line;
a fifth transmission line that is electrically connected at a first end thereof to a second end of the fourth transmission line, and that is electrically connected at a second end thereof to the second amplifier circuit, the fifth transmission line being electromagnetically coupled to the third transmission line; and
a sixth transmission line that is electrically connected to the second end of the fifth transmission line and to the second output node at a first end thereof, and that is electrically connected at a second end thereof to a reference potential, the sixth transmission line being electromagnetically coupled to the fourth transmission line.

4. The power amplifier circuit according to claim 1,
wherein the amplifier circuit comprises a first amplifier circuit and a second amplifier circuit that form a differential amplifier circuit,
wherein the impedance conversion circuit is configured to:
divide the combined signal into a first division signal and a second division signal, the second division signal having a phase opposite to a phase of the first division signal,
output the first division signal to the first amplifier circuit from a first output node of the output point, and
output the second division signal to the second amplifier circuit from a second output node of the output point, and
wherein the transmission line transformer comprises:
a seventh transmission line that is electrically connected at a first end thereof to a node between the input point and the first output node, and that is electrically connected at a second end thereof to a reference potential, and
an eighth transmission line that is electrically connected at a first end thereof to the second end of the seventh transmission line, and that is electrically connected at a second end thereof to the second output node, the eighth transmission line being electromagnetically coupled to the seventh transmission line.

5. The power amplifier circuit according to claim 1,
wherein the second-harmonic attenuation circuit comprises:
a first filter circuit that is connected in series between the combination point and a first input point receiving the first signal, and that comprises a first capacitor and a first inductor connected in parallel to each other, and
a second filter circuit that is connected in series between a reference potential and a node between the first input point and the combination point, and that comprises a second capacitor and a second inductor connected in series to each other, and
wherein the fundamental attenuation circuit comprises:
a third filter circuit that is connected in series between the combination point and a second input point receiving the second signal, and that comprises a third capacitor and a third inductor connected in parallel to each other, and
a fourth filter circuit that is connected in series between the reference potential and a node between the second input point and the combination point, and that comprises a fourth capacitor and a fourth inductor connected in series to each other.

6. The power amplifier circuit according to claim 1,
wherein, the second-harmonic attenuation circuit comprises a first line which is electrically connected at a first end thereof to a first input point receiving the first signal, and which is electrically connected at a second end thereof to the combination point, and
wherein the fundamental attenuation circuit comprises a second line which is electrically connected at a first end thereof to a second input point receiving the second signal, and which is electrically connected at a second end thereof to a reference potential, the second line being electromagnetically coupled to the first line.

7. The power amplifier circuit according to claim 1,
wherein the second-harmonic attenuation circuit comprises:
a fifth filter circuit that is connected at a first end thereof in series to a third input point receiving a first differential signal obtained through division of the first signal, and that comprises a fifth capacitor and a fifth inductor connected in parallel to each other;
a sixth filter circuit that is connected at a first end thereof in series to a fourth input point receiving a second differential signal, the second differential signal having a phase opposite to a phase of the first differential signal and being obtained through division of the first signal, and that comprises a sixth capacitor and a sixth inductor connected in parallel to each other; and
a seventh filter circuit that is electrically connected at a first end thereof to the first end of the fifth filter circuit, and that is electrically connected at a second end thereof to the first end of the sixth filter circuit, the seventh filter circuit comprising a seventh capacitor and a seventh inductor connected in series to each other,
wherein the fundamental attenuation circuit comprises:
an eighth filter circuit that is connected at a first end thereof in series to a fifth input point receiving a third differential signal obtained through division of the second signal, and that comprises an eighth capacitor and an eighth inductor connected in parallel to each other;
a ninth filter circuit that is connected at a first end thereof in series to a sixth input point receiving a fourth differential signal, the fourth differential signal having a phase opposite to a phase of the third differential signal and being obtained through division of the second signal, and that comprises a ninth capacitor and a ninth inductor connected in parallel to each other; and
a tenth filter circuit that is electrically connected at a first end thereof to the first end of the eighth filter circuit, and that is electrically connected at a second end thereof to the first end of the ninth filter circuit, the tenth filter circuit comprising a tenth capacitor and a tenth inductor connected in series to each other,
wherein a first combination node of the combination point is electrically connected to a second end of the fifth filter circuit and to a second end of the eighth filter circuit,
wherein a second combination node of the combination point is electrically connected to a second end of the sixth filter circuit and to a second end of the ninth filter circuit,
wherein the amplifier circuit comprises a first amplifier circuit and a second amplifier circuit that form a differential amplifier circuit,
wherein the impedance conversion circuit is configured to:
output a first division signal to the first amplifier circuit from a first output node of the output point, and
output a second division signal from a second output node of the output point to the second amplifier circuit, the second division signal having a phase opposite to a phase of the first division signal, and
wherein the transmission line transformer comprises:
an eleventh transmission line that is electrically connected at a first end thereof to the first combination node, and that is electrically connected to the first amplifier circuit and to the first output node at a second end thereof;
a twelfth transmission line that is electrically connected at a first end thereof to the second end of the eleventh transmission line;
a thirteenth transmission line that is electrically connected at a first end thereof to a second end of the twelfth transmission line, and that is electrically connected at a second end thereof to the second amplifier circuit, the thirteenth transmission line being electromagnetically coupled to the eleventh transmission line; and
a fourteenth transmission line that is electrically connected to the second end of the thirteenth transmission line and to the second output node at a first end thereof, and that is electrically connected at a second end thereof to the second combination node, the fourteenth transmission line being electromagnetically coupled to the twelfth transmission line.

8. The power amplifier circuit according to claim 1,
wherein the second-harmonic attenuation circuit comprises:
a third line that is electrically connected at a first end thereof to a third input point receiving a first differential signal obtained through division of the first signal, and
a fourth line that is electrically connected at a first end thereof to a fourth input point receiving a second differential signal having a phase opposite to a phase of the first differential signal obtained through division of the first signal,
wherein the fundamental attenuation circuit comprises:
a fifth line that is electrically connected at a first end thereof to a fifth input point receiving a third differential signal obtained through division of the second signal, and that is electromagnetically coupled to the third line, and
a sixth line that is electrically connected at a first end thereof to a sixth input point receiving a fourth differential signal having a phase opposite to a phase of the third differential signal obtained through division of the second signal, and that is electrically connected at a second end thereof to a second end of the fifth line through a resistor, the sixth line being electromagnetically coupled to the fourth line,
wherein a first combination node of the combination point is electrically connected to a second end of the third line,
wherein a second combination node of the combination point is electrically connected to a second end of the fourth line,
wherein the amplifier circuit comprises a first amplifier circuit and a second amplifier circuit that form a differential amplifier circuit, and
wherein the impedance conversion circuit is configured to:
output a first division signal to the first amplifier circuit from a first output node of the output point, and
output a second division signal from a second output node of the output point to the second amplifier circuit, the second division signal having a phase opposite to a phase of the first division signal,
wherein the transmission line transformer comprises:
a fifteenth transmission line that is electrically connected at a first end thereof to the first combination node, and that is electrically connected at a second end thereof to the first amplifier circuit, the second end of the fifteenth transmission line being the first output node;
a sixteenth transmission line that is electrically connected at a first end thereof to the second end of the fifteenth transmission line;
a seventeenth transmission line that is electrically connected at a first end thereof to a second end of the sixteenth transmission line, and that is electrically connected at a second end thereof to the second amplifier circuit, the seventeenth transmission line being electromagnetically coupled to the fifteenth transmission line; and
an eighteenth transmission line that is electrically connected at a first end thereof to the second end of the seventeenth transmission line, and that is electrically connected at a second end thereof to the second combination node, the eighteenth transmission line being electromagnetically coupled to the sixteenth transmission line and the second end of the eighteenth transmission line being the second output point.
